(19) United States
(12) Patent Application Publication
(10) Pub. No.: US 2026/0255726 A1
(43) Pub. Date: Aug. 27, 2026

(54) BACKSIDE-CONTACT SOLAR CELL AND METHOD FOR PRODUCING A BACKSIDE-CONTACT SOLAR CELL

(71) Applicant: Silfab Solar Cells SC Inc., Fort Mill, SC (US)

(72) Inventor: Erik HOFFMANN, Stuttgart (DE)

(21) Appl. No.: 19/643,955

(22) Filed: Apr. 10, 2026

Related U.S. Application Data
(63) Continuation-in-part of application No. PCT/EP2024/074748, filed on Sep. 4, 2024.

(30) Foreign Application Priority Data
Nov. 3, 2023 (DE) 1020231304402

(51) Int. Cl. H10F 77/70; H10F 77/30

(52) U.S. Cl. CPC H10F 77/703; H10F 77/311

(57) ABSTRACT

A back-contact solar cell and a method for manufacturing a back-contact solar cell are disclosed. The solar cell includes first, second and third regions on the back side. The first and second regions include respective first and second tunnel layers and first and second doped silicon layers. The first and second doped silicon layers are amorphous, partially crystalline or polycrystalline. The third regions do not contain amorphous, partially crystalline or polycrystalline silicon. The first and second regions are at least partially covered with a dielectric layer or stack, which includes respective first and second interruptions in the first and second regions. The solar cell includes first and second electrodes that respectively contact the first and second doped silicon layers through the first and second interruptions. The first regions are on elevations of the semiconductor substrate that have a cross-section widening in a direction perpendicular to the back side.

### CROSS-REFERENCE TO RELATED APPLICATIONS

This application is a continuation-in-part of International Pat. Appl. No. PCT/EP2024/074748, filed on Sep. 4, 2024, which claims priority to German Pat. Appl. No. 10 2023 130 440.2, filed on Nov. 3, 2023, the contents of each of which are incorporated by reference herein in its entirety.

### FIELD OF THE INVENTION

The invention relates to a back-contact solar cell with features as described herein and a method for producing a solar cell with backside contacts with such features.

### DISCUSSION OF THE BACKGROUND

In a back-contact solar cell, electrodes of opposite polarities, as well as emitter regions and base regions, are arranged on the back side of the solar cell. The back side of the solar cell is the side facing away from the sun during the operation of the solar cell. Accordingly, the front side of the solar cell is the side facing the sun.

Back-contact solar cells can generally achieve a higher efficiency than solar cells in which electrodes of one polarity are on the front side and electrodes of the opposite polarity are on the back side. In back-contact solar cells, the front side is not shaded by electrodes. To minimize resistance and recombination losses in back-contact solar cells, the electrodes of both polarities, as well as the emitter and base regions, are arranged alternately on the back side, with a small gap or distance between the different regions.

Generating a large number of p-n junctions with small spacing is technically significantly more challenging than, for example, a conventional solar cell with a large-area p-n junction. The alternately arranged emitter and base regions on the back side can be realized, for instance, using laser irradiation. In this process, n-type and p-type dopants are locally introduced into a semiconductor substrate by temporally and spatially separated melting of the surface with laser irradiation, thereby creating either a p-type or n-type doped region, depending on the dopant. Such a laser doping method is disclosed, for example, in DE 10 2013 219 564 A1. The described structuring of the back side allows efficiencies of up to 24% due to low internal series resistances and high current yields.

Even higher efficiencies are essentially limited by recombination mechanisms in the base as well as on the heavily-doped contact and non-contact surfaces. Recombination in the base depends on the quality of the semiconductor substrate, and can only be influenced to a limited extent in the manufacturing process of the solar cell. In the non-contact areas, recombination at the doped n-type and p-type surfaces is limited to Auger recombination, provided that effective surface passivation is achieved. The rate of Auger recombination increases with dopant concentration in silicon. In the contact areas, where metal electrodes contact silicon, the metal contact leads to high interface recombination. During the manufacturing process, Auger recombination at the non-contact surfaces can be reduced by minimizing doping. On the other hand, a high dopant concentration is advantageous at the contact surfaces, as this reduces contact resistance and interface recombination.

To address this discrepancy, the use of so-called passivating or charge carrier-selective contacts is known, as seen in, for example, DE 10 2013 219 564 A1 or WO 2014/100004 A1. The electrodes do not directly contact the crystalline silicon wafer, which serves as an absorber, but are separated by a thin dielectric layer, such as a silicon oxide layer. The silicon oxide layer passivates the silicon surface. Further, the silicon oxide layer is so thin that charge carriers (particularly electrons) can tunnel through the silicon oxide layer from the semiconductor to the electrode, or from the electrode to the semiconductor (depending on the polarity). Therefore, the silicon oxide layer can be referred to as a tunnel layer through which charge carriers can tunnel. The tunnel layer may also have small holes, e.g., in the nanometer (nm) range, allowing for current flow.

In order to enable only one type of charge carrier to tunnel, an electric field can be present in or across the tunnel layer. The electric field can be generated, for example, by a highly doped n-type or p-type silicon layer on the tunnel layer. Doping this highly doped silicon layer above the tunnel layer leads to band bending in the silicon base below the tunnel layer. Consequently, classical doping of the silicon base to create a p-n junction is no longer necessary. Since the silicon base is no longer doped or is only slightly doped, Auger recombination in the substrate decreases. The spatial separation of a metal/silicon interface of the electrodes from the silicon substrate also reduces interface recombination. Nevertheless, a low contact resistance can be achieved because the electrodes contact the heavily doped silicon layer. Suitable doped silicon layers are, for example, amorphous, partially crystalline, or polycrystalline silicon layers or silicon carbide layers with a thickness of 20 nm to 400 nm, which can be deposited using methods such as PECVD, LPCVD, APCVD, or PVD.

Back-contact solar cells with charge carrier-selective contacts of opposite polarities have so far achieved an efficiency of up to 26.7%. However, the production of such solar cells is complex, as the two differently-doped passivating contacts have been made only using various masking and fabrication steps. High precision and fine resolution of the masking and fabrication have been necessary. The distance between the charge carrier-selective contacts of opposite polarities should not exceed the diffusion length of the free charge carriers. However, large distances can also lead to an increase in internal series resistance due to lateral current flow in the base.

The differently-doped silicon layers of the charge carrier-selective contacts can also be separated either by an undoped silicon layer or by a spatial separation (e.g., a trench or an interruption). Without such separation, the transition between the differently-doped layers forms a defect-rich p-n junction, which limits the efficiency of the solar cell. Ideally, the separation should be as fine as possible, as a large separation can adversely affect the short-circuit current and the open-circuit voltage.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

It is therefore an object of the present invention to provide a back-contact solar cell and a method for manufacturing a back-contact solar cell, whereby the solar cell has a high efficiency and can be produced cost-effectively and efficiently.

This object is provided by a back-contact solar cell with features as described herein. The solar cell comprises a semiconductor substrate (e.g., a monocrystalline silicon wafer, or other semiconductor substrate formed from silicon). The back side of the semiconductor substrate includes a plurality of first regions, a plurality of second regions and a plurality of third regions. The first regions each comprise a first doped silicon layer. The second regions each comprise a second doped silicon layer. The first doped silicon layer and the second doped silicon layer can have dopants with different or opposite polarities (e.g., one of the first and second doped silicon layers contains an n-type dopant or a p-type dopant, and the other of the first and second doped silicon layers contains the other of the n-type dopant or the p-type dopant). The first doped silicon layers and the second doped silicon layers are each amorphous, partially crystalline or polycrystalline. Each of the third regions are without amorphous, partially crystalline or polycrystalline silicon. The first regions and the second regions may be passivating contacts. A first tunnel layer is between the first doped silicon layers and the semiconductor substrate. A second tunnel layer is between the second doped silicon layers and the semiconductor substrate.

A surface on the back side of the semiconductor substrate or solar cell, or surfaces on both the back side and the front side of the semiconductor substrate or solar cell can be at least partially, and optionally completely, covered with a dielectric (passivating) layer. The dielectric layer can comprise or consist essentially of a layer stack, that is, a plurality pf layers (e.g., in which adjacent layers contain different dielectric materials). The dielectric (passivating) layer can have a first interruption, gap or opening in each of the first regions, and a second interruption, gap or opening in each of the second regions. The dielectric layer thus has a plurality of first interruptions, openings or gaps and a plurality of second interruptions, openings or gaps, particularly on the back side of the semiconductor substrate or the solar cell. The solar cell has a plurality of first electrodes and a plurality of second electrodes. The first electrodes can electrically contact the first doped silicon layer, in particular, through the first interruptions, gaps or openings. The second electrodes can electrically contact the second doped silicon layer, in particular, through the second interruptions, gaps or openings.

The first regions are on platform-like elevations of the semiconductor substrate. The elevations each have a cross-section that widens (i.e., becomes larger) in a first direction. In particular, the shape of the cross section of the platform-like elevations can be trapezoidal. The pedestal-like elevations of the semiconductor substrate can each have a cross-section that is rounded in a first direction, or, tapers (i.e., gets smaller), or maintains a constant width (i.e., has substantially vertical sidewalls). In particular, the shape of the cross-section of the pedestal-like elevations can be trapezoidal or rectangular.

As a result, the third regions can be in a retracted region widening transversely to the first direction, and thus be quasi in the “shadow” (with respect to the first direction) of the first regions. The first doped silicon layers and the second doped silicon layers, in particular in the first and second regions, respectively, are therefore separated from one another by the third regions. The third regions may form a step or space in the “shadows” of the first regions. As a result, separate, differently-doped charge carrier-selective contacts with a fine separation of a few micrometers and a high resolution can be implemented without further complex structuring or manufacturing steps. This separation makes it possible to avoid formation of a p-n junction between the first and second doped silicon layers, which would in particular limit the fill factor and thus also the efficiency. A solar cell with a high efficiency can therefore be implemented, which can be produced cost-effectively and efficiently.

The first direction may refer to a direction pointing away from the back side of the solar cell. The first direction is, more particularly, perpendicular to the front and/or back sides of the solar cell or semiconductor substrate.

The first doped silicon layers can be p-type or n-type (or positive type or negative type) layers. The second doped silicon layers can also be p-type or n-type layers. The first conductive layers and the second conductive layers are amorphous, partially crystalline, or polycrystalline, and thus, can have a different morphology from the semiconductor substrate (or silicon base), which may be crystalline, especially monocrystalline.

The widening cross-section of the platform-like elevations can be implemented by undercutting (see the discussion below). As a result, the third regions can have a width (e.g., a transverse dimension with respect to the first direction) in a range from 0.5 μm to 20 μm (micrometers), in particular in a range from 1 μm to 10 μm, which contains no amorphous, partially crystalline or polycrystalline silicon or silicon layer.

According to an embodiment of the solar cell, the third regions can be undercut regions. As a result, the third regions can be implemented simply.

According to an embodiment of the solar cell, the third regions can be undoped.

In the present context, “undoped” means that no additional (process-related) doping is performed. An undoped layer may be an intrinsic layer or may have the same doping (type and concentration) as the semiconductor substrate. The semiconductor substrate can have a low doping, for example, about 5×10¹⁶ cm⁻³. An “undoped” layer can therefore have the same doping or a low doping similar to that of the substrate. Accordingly, “doped” refers to a layer or structure having additional doping, relative to the semiconductor substrate.

As a result, the third regions can be implemented simply. In particular, the present invention can implement a distinct (undoped) separation between the first doped silicon layers and the adjacent second doped silicon layers.

According to one embodiment, the third regions can have a third doped silicon layer. The surface of the semiconductor substrate (which may be crystalline or monocrystalline) in the third regions can be doped. This can further improve the efficiency of the solar cell.

According to an embodiment of the solar cell, a fourth doped silicon layer can be on or in the front side of the solar cell. The fourth conductive layer may be or comprise a doped silicon layer. This can further improve the efficiency of the solar cell.

The semiconductor substrate, the first doped silicon layers, the second doped silicon layers, the third doped silicon layers (or third regions) and/or the fourth doped silicon layer may have a doping according to one of the combinations in Table 1 below:

TABLE 1

| | | | Third | Front side |
|---|---|---|---|---|
| | First | Second | conductive | or fourth |
| Semiconductor | conductive | conductive | layer or | conductive |
| substrate | layer | layer | third region | layer |
| n | n | p | — | p |
| n | n | p | — | n |
| n | n | p | p | p |
| n | n | p | n | n |
| n | p | n | — | p |
| n | p | n | — | n |
| n | p | n | p | p |
| n | p | n | n | n |
| p | n | p | — | p |
| p | n | p | — | n |
| p | n | p | p | p |
| p | n | p | n | n |
| p | p | n | — | p |
| p | p | n | — | n |
| p | p | n | p | p |
| p | p | n | n | n |
| p | n | p | — | — |
| p | n | p | — | — |
| p | n | p | p | — |
| p | n | p | n | — |
| p | p | n | — | — |
| p | p | n | — | — |
| p | p | n | p | — |
| p | p | n | n | — |
| n | n | p | — | — |
| n | n | p | — | — |
| n | n | p | p | — |
| n | n | p | n | — |
| n | p | n | — | — |
| n | p | n | — | — |
| n | p | n | p | — |
| n | p | n | n | — |

Here, and in particular in Table 1, “p” refers to an additional positive (or p-type) doping compared to the semiconductor substrate, “n” refers to an additional negative (or n-type) doping compared to the semiconductor substrate, and “-” means no additional doping compared to the semiconductor substrate. As a result, the solar cell can be designed and implemented as flexibly as possible.

According to an embodiment of the solar cell, the first doped silicon layers, the second doped silicon layers, the first tunnel layers and/or the second tunnel layers can each be free of openings or apertures. The first and/or second tunnel layers may each be closed layers. In particular, the first tunnel layers and/or the second tunnel layers are not broken through, opened or penetrated, or are only slightly broken through, opened or penetrated, by the first electrodes and/or the second electrodes. This can further improve the efficiency of the solar cell.

According to an embodiment of the solar cell, the first doped silicon layers, the second doped silicon layers, first tunnel layers and/or the second tunnel layers can each be broken through or penetrated by an aluminum-silicon eutectic. The aluminum-silicon eutectic may be on or under the respective first electrode and/or the respective second electrode. This can further improve the efficiency of the solar cell.

According to an embodiment of the solar cell, the aluminum-silicon eutectic can be surrounded at least in part by a fifth doped silicon layer. The fifth doped silicon layer can have a p-type doping (for example, aluminum) or an n-type doping. If an aluminum-silicon eutectic is on or under the first electrodes and/or the second electrodes, the fifth doped silicon layer can have a polarity which corresponds to the polarity of the respective electrode. In particular, the fifth doped layers surrounding the eutectics on or under the first electrodes may have a polarity opposite from that or the fifth doped layers surrounding the eutectics on or under the second electrodes.

This can further improve the efficiency of the solar cell. In addition, the production or manufacturing of the solar cell can be implemented more cost-effectively.

The above object is also achieved by a method for producing a back-contact solar cell in accordance with one or more of the above embodiments, having some or all the features described herein. The method comprises:
providing a semiconductor substrate having a front side and a back side;
forming a first tunnel layer on the back side of the semiconductor substrate;
forming a first doped silicon layer having a first polarity on the first tunnel layer;
forming an etch-stable barrier layer on the first doped silicon layer;
removing the etch-stable barrier layer in a plurality of etching regions;
etching the first doped silicon layer, the first tunnel layer and the semiconductor substrate (e.g., a surface of the semiconductor substrate) in the etching regions, to form platform-like elevations of the semiconductor substrate having a cross-section widening in a first direction; and
forming a second doped silicon layer having a second polarity opposite to the first polarity in the regions between the pedestal-like elevations (e.g., the second regions in the present solar cell), but not in regions under the widening cross-section of the pedestal-like elevations (e.g., the third regions in the present solar cell).

The etching may include under-etching, in particular of one or more layers and/or the substrate below the etch-stable barrier layer. The platform-like elevations thus extend out of the semiconductor substrate. The etching can comprise wet chemical etching.

In particular, the etch-stable barrier layer may be completely removed (e.g., on the pedestal-like elevations) after etching the first doped silicon layer, the first tunnel layer and the semiconductor substrate. The method may further comprise forming a second tunnel layer in the regions between the pedestal-like elevations of the semiconductor substrate (e.g., the second regions in the present solar cell).

The third regions may not contain amorphous, partially crystalline or polycrystalline silicon.

At least some of the advantages that can be provided by the method are described in details relating to the solar cell. Further embodiments of the method are described in connection with the solar cell and/or certain details of the present method explained below.

According to an embodiment of the method, the method can further comprise forming third doped silicon layers in the regions under the widening cross-section of the pedestal-like elevations and/or a fourth doped silicon layer on a front side of the semiconductor substrate by a furnace diffusion (e.g., heating the device with a removable dopant-containing layer in the regions under the widening cross-section of the pedestal-like elevations and/or on the front side of the semiconductor substrate at a temperature and for a length of time sufficient to diffuse the dopant from the dopant-containing layer into the semiconductor substrate).

According to an embodiment of the method, the method can further comprise removing a product formed during the furnace diffusion (e.g., the removable dopant-containing layer), preferably after the furnace diffusion is complete. The removable dopant-containing layer may comprise a silicate glass layer, for example a phosphosilicate glass or a borosilicate glass. The removable dopant-containing layer may be removed in particular by etching (e.g., wet chemical etching).

According to an embodiment of the method, the method can further comprise forming the first electrodes and/or the second electrodes and/or forming the aluminum-silicon eutectic on the first electrodes and/or the second electrodes using a paste or paste stack, in particular wherein the pastes or paste stacks contain a p-type dopant, in particular aluminum, and/or an n-type dopant.

The method may comprise, in particular, etching the first doped silicon layer, the first tunnel layer and/or the semiconductor substrate by anisotropic or isotropic wet chemical etching. The wet chemical etching can be carried out after depositing or growing the first tunnel layer, depositing the first doped silicon layer, depositing the etch-stable barrier layer and structuring (e.g., patterning) the etch-stable barrier layer. The etch-stable barrier layer may be patterned, for example by laser irradiation. The wet chemical etching can remove silicon along the first direction (i.e., perpendicular to the surface of the semiconductor substrate), for example, to a depth of approximately 0.5 μm to 20 μm, in particular 1 μm to 10 μm (etching depth). In this case, wet chemical etching also underetches the etch-stable barrier layer and, in some cases, the first doped silicon layer (depending on whether the first doped silicon layer has chemical properties providing a sufficiently high etch stability or resistance), independently of whether the wet chemical etch is or is designed to be anisotropic or isotropic.

Subsequent to etching the first doped silicon layer, the first tunnel layer and/or the semiconductor substrate (e.g., the wet chemical etch), the etch-stable barrier layer may be removed.

After growing a second tunnel layer, which may passivate the exposed surface of the semiconductor substrate, the second doped silicon layer may be deposited, for example, by physical vapor deposition (PVD). Unlike conventional chemical vapor deposition methods (PECVD, LPCVD, APCVD), in PVD, little or no material (e.g., silicon or doped silicon) is deposited transversely with respect to the first direction (i.e., on surfaces parallel to the deposition direction of the material). In particular, no material is deposited by PVD in the present method in the regions under the widening cross-section of the pedestal-like elevations (e.g., the undercut regions). Thus, the undercut regions may not include either the first doped silicon layer or the second doped silicon layer. The p-n junction can thus be situated exclusively in or on the semiconductor substrate (silicon wafer), and thus, the solar cell can have low recombination. A high fill factor and a high efficiency can thus be achieved.

In other words, when removing the first doped silicon layer, the first tunnel layer and the semiconductor substrate by wet chemical etching in regions in which the etch-stable barrier layer has been removed, isotropic or anisotropic undercutting of the etch-stable barrier layer occurs. The deposition of the second doped silicon layer may comprise physical, directed (e.g., unidirectional) gas phase deposition. As a result, the second doped silicon layer does not deposit on all exposed surfaces on the back side of the solar cell, but is interrupted at least in shaded (undercut) regions. Thus, no further processing is required for separating the first doped silicon layer in the first regions and the second doped silicon layer in the second regions (i.e., the two differently doped silicon layers that form ohmic contact with the electrodes). Furthermore, this separation (i.e., the regions without the first and second doped silicon layers) extends over a distance of a few to a few tens of micrometers (the sum of the etching depth and the width of the undercut region). This allows facile ultra-fine separation (in the micrometer range) of charge carrier selective contacts in back-contact solar cells.

### BRIEF DESCRIPTION OF THE DRAWINGS

Further features, details, and advantages of the invention appear from the wording of the claims as well as from the following description of embodiments with reference to the drawings, which show:

FIG. 1 schematically shows an exemplary back-contact solar cell according to a first embodiment;

FIG. 2 schematically shows an exemplary back-contact solar cell according to a second embodiment;

FIG. 3 schematically shows an exemplary back-contact solar cell according to a third embodiment;

FIG. 4 is a scanning electron image showing first, second and third regions of a solar cell according to the representations of FIGS. 1 to 3;

FIGS. 5 to 16 schematically show an exemplary method of making a back-contact solar cell according to a first embodiment; and

FIGS. 17 to 28 show an exemplary method of making a back-contact solar cell according to a second embodiment.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

In the following description and in the figures, corresponding components and elements are marked with the same reference signs. For better clarity, not all reference signs are shown in every figure.

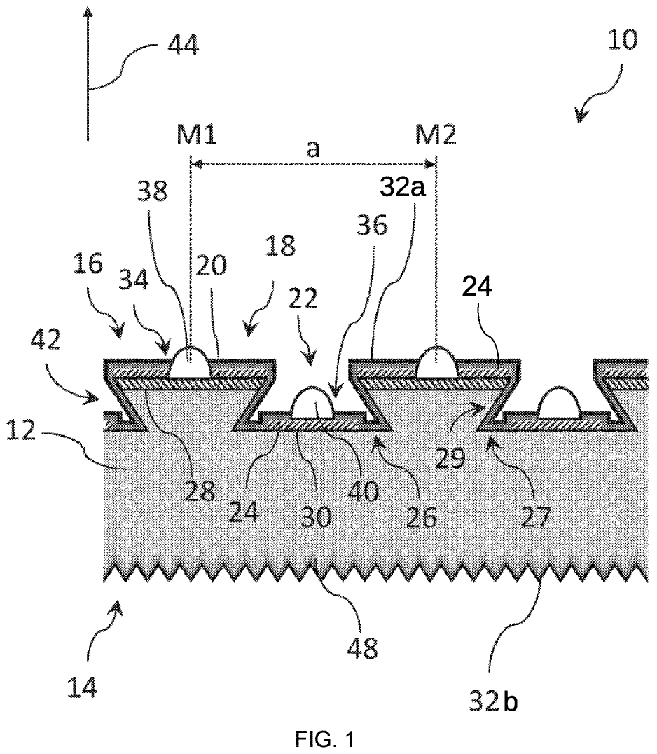

FIG. 1 shows a schematic cross-section of a solar cell 10 with back side contacts according to a first exemplary embodiment. In the example, the solar cell 10 comprises a crystalline n-type semiconductor substrate 12. The semiconductor substrate 12 in the present case forms a silicon base 12. In another embodiment, it may also be a crystalline p-type silicon base 12.

The solar cell 10 comprises a front side 14 and a back side 16. In the exemplary embodiment shown, the front side 14 may be textured. The back side 16 of the solar cell 10 includes a plurality of first regions 18 each having a first doped silicon layer 20, a plurality of second regions 22 each having a second doped silicon layer 24, and a plurality of third regions 26. In this embodiment, the second doped silicon layer 24 is also in the first regions 10, in each case above the first doped silicon layer 20. The second doped silicon layer 24 in the first regions 18 may not be functional, or add a new function to that of the first doped silicon layer 20.

The first doped silicon layers 20 and the second doped silicon layers 24 are each amorphous, partially crystalline or polycrystalline. They thus differ from the (mono) crystal silicon base 12 (or the semiconductor substrate 12). Each of the third regions 26 do not contain amorphous, partially crystalline or polycrystalline silicon. In the first regions 18, a first tunnel layer 28 is between the first doped silicon layer 20 and the semiconductor substrate 12. In the second regions 22, a second tunnel layer 30 is between the second doped silicon layer 24 and the semiconductor substrate 12. The second tunnel layer 30 may be between the second doped silicon layer 24 and the first doped silicon layer 20 in the first regions 18.

The first regions 18 and the second regions 22 may each be or comprise a passivating contact. In the present case, a surface of the back side 16 and of the front side 14 of the solar cell 10 is at least partially, in particular completely, covered with a dielectric layer or dielectric layer stack 32a-b. The dielectric layer/stack 32a-b may comprise two layers. The dielectric layer/stack 32a-b may passivate the front side 14 and/or the back side 16, reduce reflections at the front side 14, and/or improve light absorption of the solar cell 10. The dielectric layer/stack 32a-b may comprise, for example, an aluminum oxide (AlOx, such as alumina or Al₂O₃), a silicon oxide (SiOx, such as doped or undoped SiO₂), silicon nitride (SiNx; Si₃N₄), or a combination or laminate thereof. The dielectric layer/stack 32a-b can comprise a layer stack (i.e., a plurality of dielectric layers). The layer stack can comprise two or more layers, for example, selected from an aluminum oxide, a silicon oxide, and silicon nitride. Other layers for reducing the reflection at the front side 14, improve light absorption of the solar cell 10, and/or improving the passivation are also conceivable. The dielectric layer or layer stack 32b on the front side 14 and the dielectric layer or layer stack 32a on the back side 16 can be identical to or different from each other.

The dielectric layer/stack 32a has a first interruption or opening 34 in the first regions 18 and a second interruption or opening 36 in the second regions 22. The first interruption or opening 34 may or may not pass through the second doped silicon layer 24 and, optionally, the second tunnel layer 30 in the first regions 18 to the first doped silicon layer 20.

The solar cell 10 comprises a plurality of first electrodes 38 and a plurality of second electrodes 40. In each case, the first electrodes 38 may contact the first doped silicon layer 20 through a first interruptions or openings 34, in which case the first electrode 38 may penetrate the second doped silicon layer 24. It is likewise conceivable that the second doped silicon layer 24 can represent or comprise a (further) tunnelling connection in the region of the first interruption 34, in which case the first electrode 38 passes through only the dielectric layer/stack 32a, and contacts only the second doped silicon layer 24 in the first tunnel dielectric-first doped silicon-second tunnel dielectric-second doped silicon layer stack. The second electrodes 40 contact the second doped silicon layer 24 through the second interruptions or openings 36. The first regions 18 are on platform-like elevations 42 of the semiconductor substrate 12. The elevations 42 each have a cross-section that widens in a first direction 44. In other words, the cross-section of the elevations 42 narrows in a direction opposite to the first direction 44. The third regions 26 can be undoped.

In the examples shown in the drawings, the front side 14 includes a fourth doped silicon layer 48. The fourth silicon layer 48 can form a so-called “front floating emitter” (FFE), or an emitter with a p-n junction (i.e., where the fourth doped silicon layer 48 has a doping opposite to that of the semiconductor substrate 12). The fourth doped fourth silicon layer 48 may be doped with a p-type dopant, for example boron, in particular with a dopant concentration of approximately 5×10¹⁷ cm⁻³ to 1×10²⁰ cm⁻³, preferably about 5×10¹⁸ cm⁻³ to 5×10¹⁹ cm⁻³.

In a further, alternative embodiment, the fourth doped silicon layer 48 can include an n-type doping, in particular with a comparable or identical dopant concentration as that described in the previous paragraph. In this case, the doping on the front side is referred to as a “front surface field” (FSF), i.e. in which the doping in the fourth doped silicon layer 48 is equal to or of the same type as (but greater than) the doping of the silicon base 12.

A surface of the back side 16 can be textured over the entire surface or can be chemically polished over the entire surface, for example. The surface of the back surface 16 may also include a combination of textured regions and polished regions. For example, the surface may be polished in the first regions 18 and textured in the second regions 22 (or vice versa). Chemical polishing refers to treatment of the surface by anisotropic silicon etching, for example with hot potassium hydroxide solution.

The first doped silicon layers 20 may comprise n-type doped polycrystalline silicon. The second doped silicon layers 24 may comprise p-type doped polycrystalline silicon. In the present case, the second doped silicon layer 24 is in each of the first regions 18, above the first doped silicon layers 20 (e.g., with respect to the first direction 44). The second doped silicon layers 24 in the first regions 18 typically do not add further functionality to the layer stack in the first regions 18, although they also generally do not significantly affect the functionality of the other layers in the layer stack.

In the present case, the first regions 18 and the second regions 22 alternate with one another (e.g., along a direction orthogonal to the first direction, in a plane parallel to the substrate 12). A distance a between a center M1 of a first (e.g., n-type doped) region 18 and a center M2 of a next (e.g., n-type doped) first region 18 is, for example, from 100 μm to 3000 μm, or any value or range of values therein (e.g., between 300 μm and 3000 μm, preferably between 400 μm and 2000 μm). Accordingly, a distance between a center of a second region 22 (which may be doped with a p-type dopant) and a center of a next second region (which may also be doped with a p-type dopant) is, for example, from 100 μm to 3000 μm, or any value or range of values therein (e.g., between 300 μm and 3000 μm, preferably between 400 μm and 2000 μm).

Over the area of the back side 16 of the solar cell, a ratio of the total area of the second regions 22 (e.g., p-type doped regions) to the total area of the first regions 18 (e.g., n-type doped regions) is in particular between 1:9 to 9:1, in particular 2:8 to 8:2, preferably between 3:7 to 7:3. The alternating pattern can, however, also be interrupted locally, for example in regions including bus bars.

The layer thickness of the first doped silicon layers 20 and/or of the second doped silicon layers 24 can be, for example, from 20 nm to 400 nm. The first doped silicon layers 20 and the second doped silicon layers 24 can have the same thickness. It is likewise conceivable that the first doped silicon layers 20 and the second doped silicon layers 24 can have different thicknesses.

The first doped silicon layers 20 and/or the second doped silicon layers 24 may be doped with an n-type dopant, e.g. phosphorus, and with a dopant concentration of, for example, approximately 1×10¹⁹ cm⁻³ to 1×10²¹ cm⁻³, preferably about 5×10¹⁹ cm⁻³ to 2×10²⁰ cm⁻³.

The first and/or second tunnel layers 28, 30 can each be or comprise a dielectric layer. The first and/or second tunnel layers 28, 30 may include, for example, a layer comprising silicon oxide (SiOx) or a layer comprising a silicon oxynitride (SiON).

The first and/or second tunnel layers 28, 30 may passivate the surface of the semiconductor substrate 12 (or the silicon base 12). The first and/or second tunnel layers 28, 30 may have, for example, a thickness of 0.5 nm to 20 nm, or any value or range of values therein (e.g., 0.5 nm to 4 nm). This in particular enables tunnelling of charge carriers.

The first and/or second tunnel layers 28, 30 can each be free of apertures. It is likewise conceivable that the first and/or second tunnel layers 28, 30 may have openings, or so-called pinholes, having a size or diameter in the nm range. As a result, ohmic contact between the semiconductor substrate 12 (silicon base 12) and the first doped silicon layer 20 or the second doped silicon layer 24 can be implemented.

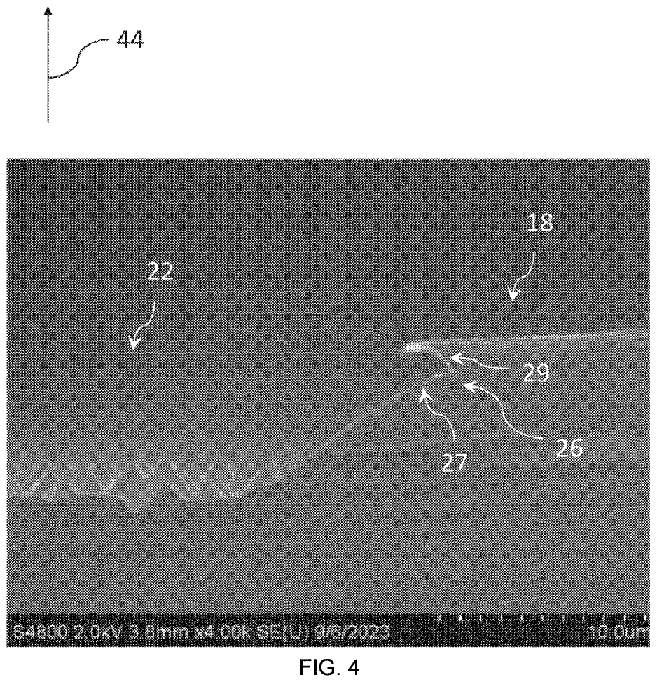

The first doped silicon layers 20, in particular in the first regions 18, and the second doped silicon layers 24, in particular in the second regions 22, are separated from one another in the present case by the third regions 26. The third regions 26 are formed in the present case from a volume of silicon undercut from the semiconductor substrate 12 or the silicon base 12. The third regions 26 can include a first (lateral) sub-region 27 and a second (vertical or angled) sub-region 29. In this case, the first sub-region 27 can be oriented transversely (perpendicular) to the first direction 44 and the second sub-region 29 can be oriented at an inclination or angle to the first direction 44 (e.g., an angle other than n*90°, where n is an integer of 0 or greater). It is likewise conceivable that both the first sub-regions 27 and the second sub-regions 29 (or a cross-section thereof) can each be oriented at an inclination or angle relative to the first direction 44 (e.g., an angle other than n*90°, where n is an integer of 0 or greater), and that the first sub-regions 27 and the second sub-regions 29 can be curved or non-planar (see, for example, FIG. 4).

In particular, no or only very small amounts of the second doped silicon layer 24 are present in the third regions 26, and there is therefore no p-n junction between the first doped silicon layers 20 in the first regions 18 and the second doped silicon layers 24 in the second regions 22. The dopant concentration of the third regions 26 therefore may correspond to the dopant concentration of the silicon base 12. Additionally, or alternatively, the surface of the third regions 26 may be covered with the dielectric layer or dielectric layer stack 32. For this purpose, the dielectric layer or dielectric layer stack 32, in contrast to the second doped silicon layer 24, can be formed non-directionally, and can also be present in the third regions 26.

The dielectric layer 32 essentially passivates the surface of the silicon base 12 or the semiconductor substrate 12. The dielectric layer 32 may also serve as a hydrogen source for improving the passivation with the first or second tunnel layers 28, 30, and it may also saturate open bonds in the third regions 26 and improve the passivation (e.g., in the third regions 26) by the field effect. The dielectric layer 32 can also optimize optical properties of the solar cell 10, in particular if the solar cell 10 is bifacial. The dielectric layer 32 comprises, for example, an aluminum oxide (AlOx; e.g., Al₂O₃), a silicon oxide (SiOx; e.g., SiO₂), and/or silicon nitride (SiNx; e.g., Si₃N₄). The dielectric layer 32 can consist of a layer stack comprising at least two layers, for example comprising AlOx, SiOx and/or SiNx. Other layers for reducing reflections in the solar cell 10 and/or improving the passivation are also conceivable.

In the examples shown in the drawings, the dielectric layer 32 covers almost the entire surface of the back side 16 and substantially the entire surface of the front side 14.

First and second interruptions 34, 36 may be provided or made in the dielectric layer or dielectric layer stack 32 on the back side 16, which interruptions can be formed, for example, as openings. Alternatively, the first and second interruptions 34, 36 can also be formed by firing a metal-containing layer on the dielectric layer or dielectric layer stack 32, which dissolves, melts or otherwise breaks through the dielectric layer or dielectric layer stack 32 during the firing process. The first and second interruptions 34, 36 enable electrical contact between the first and second electrodes 38, 40 and the first and/or second doped silicon layers 20, 24.

For this purpose, the second doped silicon layers 24 and the second tunnel layers 30 can likewise each have an interruption in the first regions 18 in order to make it possible to contact the first electrodes 38 with the respective first doped silicon layer 20 (see, for example, FIG. 1). These interruptions can be formed analogously to the first and/or the second interruptions 34, 36 and substantially simultaneously with the first interruptions 34.

The first and/or second interruptions 34, 36 can be, for example, continuous or round, angular or linear, or segmented. Accordingly-shaped contact areas can thus be provided for the first and second electrodes 38, 40 (for example, point or circular contact areas, or linear or segmented contact areas).

In the examples shown in the drawings, the first electrodes 38 contact the first doped silicon layers 20, which in one case are doped with an n-type dopant. The first electrodes 38 may therefore also be referred to as negative electrodes. In the examples shown, the second electrodes 40 contact the second doped silicon layers 24, which in one case are doped with a p-type dopant. The second electrodes 40 can therefore also be referred to as positive electrodes.

The first and second (e.g., negative and positive) electrodes 38, 40 can comprise or consist essentially of one or more metals, for example silver, copper and/or aluminum. The first and second electrodes 38, 40 can be embodied, for example, as layer stacks of silver and copper, in order, for example, to reduce or minimize the silver content of the electrode metallization. In some embodiments, the first tunnel layer 28 is formed without interruptions (as a closed layer) in the first region 18. In some additional or alternative embodiments, the second tunnel layer 30 is formed without interruptions (as a closed layer) in the second region 22. It is likewise conceivable for the first and/or the second tunnel layers 28, 30 to be interrupted in the locations of the first and/or second interruptions 34, 36.

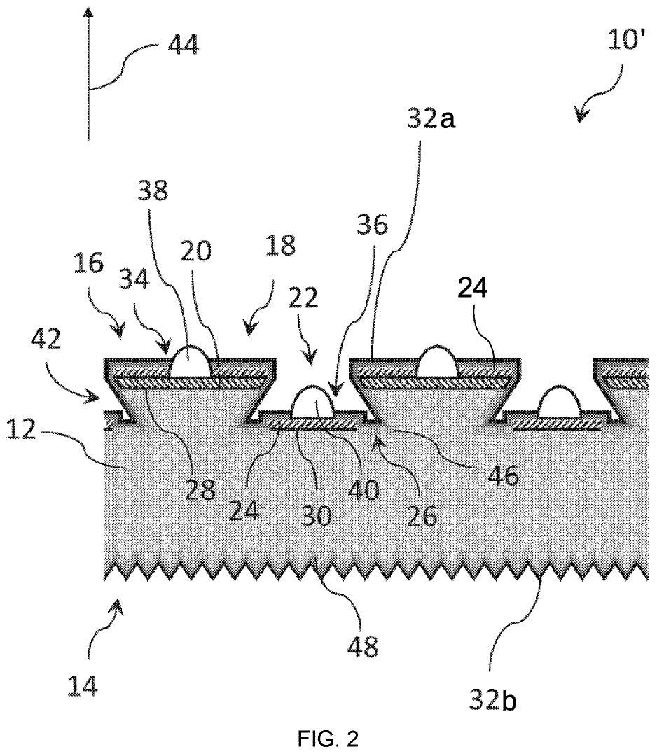

FIG. 2 shows a schematic cross section of the solar cell 10 with contacts on the back side 16 according to a second exemplary embodiment. The second embodiment (e.g., solar cell 10′) differs from the first embodiment shown in FIG. 1 in the following: In particular, the surface of the semiconductor substrate 12 (and in particular, the back side 16 of the semiconductor substrate 12) can be further doped in the third regions 26 such that the dopant concentration in the third regions 26 exceeds the dopant concentration of the semiconductor substrate 12. The third regions 26 in the second embodiment have a third doped silicon layer 46. In addition, the second tunnel layer 30 is not present, or has been removed, in the third regions 26. The third doped silicon layer 46 can be doped, for example, with an n-type or a p-type dopant. This additional doping (compared to the semiconductor substrate 12) may improve the passivation in the third regions 26. Depending on the doping of the third doped silicon layer 46, a p-n junction can be formed between the third doped silicon layer 46 and either or both of the first (e.g. p-type) doped silicon layer 20 and the second (e.g. n-type) doped silicon layer 24.

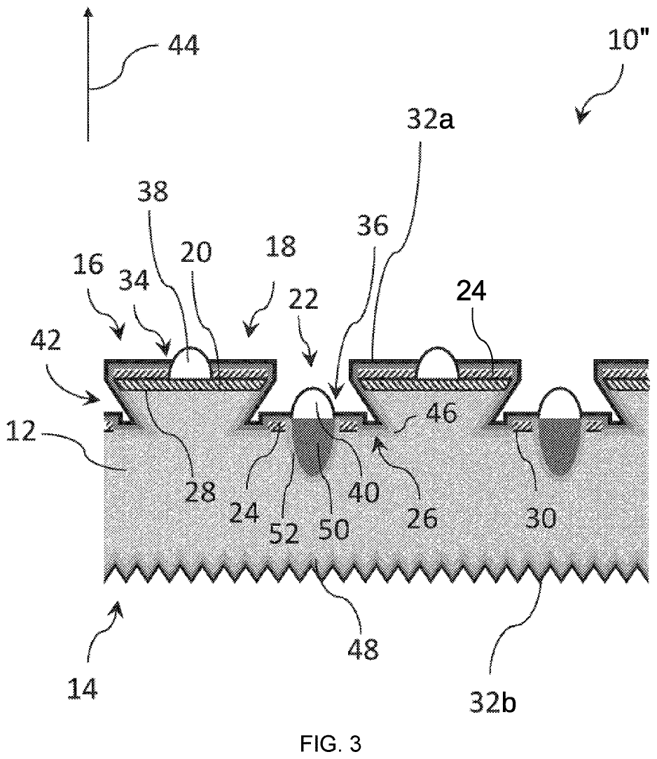

FIG. 3 shows a schematic cross section of a solar cell 10″ with contacts on the back side 16 according to a third exemplary embodiment. The third embodiment differs from the second embodiment shown in FIG. 2 in the following:

In the third embodiment, the second electrodes 40 (for example, positive electrodes) may comprise aluminum alloying electrodes. An aluminum-silicon eutectic 50 is at the locations of the second interruptions 36 in the dielectric layer or dielectric layer stack 32. The aluminum-silicon eutectic 50 breaks through or penetrates the second doped silicon layer 24 and the second tunnel layer 30. The aluminum-silicon eutectic 50 is on or below the second electrodes 40 (e.g., the bottommost surface thereof). The aluminum-silicon eutectic 50 may be surrounded at least in sections by a fifth doped silicon layer 52. In other words, the silicon (e.g., of the semiconductor substrate or base 12) in the layer 52 around the eutectic 50 contains a dopant. The dopant can be or comprise aluminum. In the example with an n-type semiconductor substrate 12 (e.g., the silicon base 12), an aluminum-doped emitter is formed, which may surround the eutectic 50. In another embodiment with a p-type semiconductor substrate 12, an aluminum-doped back side field (Al-BSF) may form at the second interruptions 36.

It is likewise conceivable that the first electrodes 38 may have a similar eutectic therebelow, with a fifth or sixth doped silicon layer surrounding the eutectic. The fifth or sixth doped silicon layers surrounding the eutectics below the first electrodes 38 and the fifth doped silicon layers 52 surrounding the eutectics 50 below the second electrodes 40 can have opposite polarities. The doping type of the respective eutectic can correspond to the polarity of the respective electrodes 38, 40 or correspond to the respective first or second doped silicon layers 20, 24.

It is also conceivable that the above-described aluminum electrodes are present in combination with the first exemplary embodiment of the solar cell 10 according to FIG. 1.

The semiconductor substrate 12, the first doped silicon layers 20, the second doped silicon layers 24, the third doped silicon layers 46, the fourth doped silicon layer 48 and/or the third regions 26 of the solar cell 10 according to one of the three exemplary embodiments described above can each have a doping according to one of the combinations according to Table 1.

TABLE 1

| | | | Third | Front side |
|---|---|---|---|---|
| | First | Second | conductive | or fourth |
| Semiconductor | conductive | conductive | layer or | conductive |
| substrate | layer | layer | third region | layer |
| n | n | p | — | p |
| n | n | p | — | n |
| n | n | p | p | p |
| n | n | p | n | n |
| n | p | n | — | p |
| n | p | n | — | n |
| n | p | n | p | p |
| n | p | n | n | n |
| p | n | p | — | p |
| p | n | p | — | n |
| p | n | p | p | p |
| p | n | p | n | n |
| p | p | n | — | p |
| p | p | n | — | n |
| p | p | n | p | p |
| p | p | n | n | n |
| p | n | p | — | — |
| p | n | p | — | — |
| p | n | p | p | — |
| p | n | p | n | — |
| p | p | n | — | — |
| p | p | n | — | — |
| p | p | n | p | — |
| p | p | n | n | — |
| n | n | p | — | — |
| n | n | p | — | — |
| n | n | p | p | — |
| n | n | p | n | — |
| n | p | n | — | — |
| n | p | n | — | — |
| n | p | n | p | — |
| n | p | n | n | — |

FIG. 4 shows a scanning electron image of an intermediate structure including first, second and third regions 18, 22 and 26, suitable for the solar cell 10, 10′ or 10″ according to the exemplary embodiments described above. The third regions 26 were produced in the structure in FIG. 4 by undercutting (e.g., wet chemical etching).

In the case of a unidirectional, directed deposition (for example, physical vapor deposition [PVD]), the material being deposited is deposited exclusively or nearly exclusively on a free or exposed surface, that is to say outside the illustrated third region 26 (or outside the undercut region). The third region 26 therefore leads to an interruption in a unidirectionally deposited layer (for example, the second doped silicon layer 24 [not present in FIG. 4]).

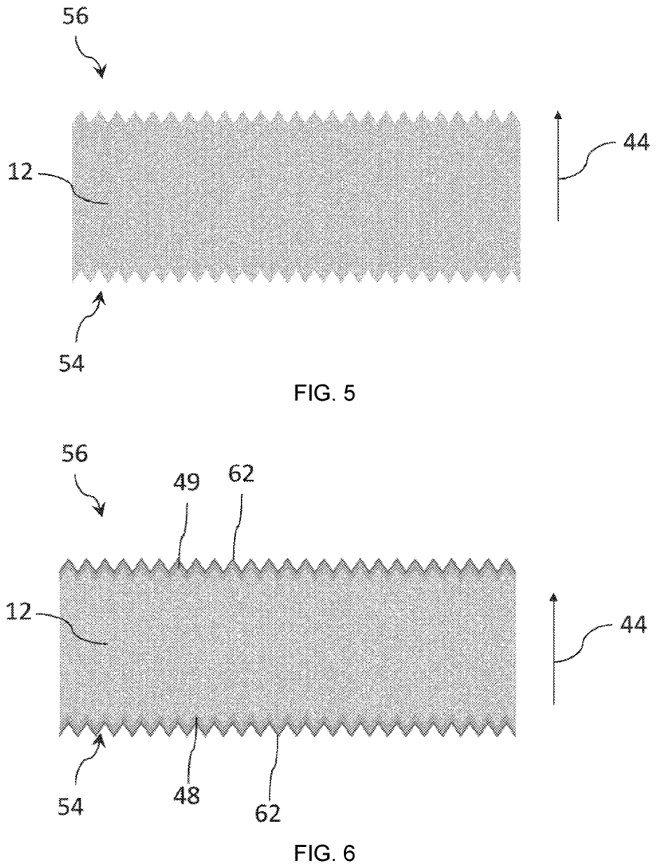

FIGS. 5 to 16 show a method for producing a back-contact solar cell 10 according to a first exemplary embodiment. With the method shown, the solar cell 10 can be produced according to the above embodiments, in particular according to the first embodiment shown in FIG. 1.

First, FIG. 5 shows a semiconductor substrate 12 (or silicon wafer 12) having a front side 54 and a back side 56. The front side 54 of the semiconductor substrate 12 corresponds in particular to the front side 14 of the solar cell 10. Accordingly, the back side 56 of the semiconductor substrate 12 corresponds to the back side 16 of the solar cell 10. The direction of deposition of the second doped silicon layer 24 by PVD corresponds in particular to the opposite direction of the first direction 44. In other words, the deposition direction of the second doped silicon layer 24 is oriented opposite to the first direction 44.

First, the semiconductor substrate 12 may be textured with an isotropic etch on, in particular, the front side 54 and/or the back side 56. An additional etch prior to texturing to remove saw damage is possible. Other methods for texturing are also conceivable.

The semiconductor substrate 12 can be subjected to full-area diffusion, for example oven or furnace diffusion, for doping the surfaces on, in particular, the front side 54 and the back side 56, or alternatively, the front side 54 only. The full-area diffusion can dope the substrate 12 with either a p-type or an n-type dopant (for example, boron or phosphorus). Thus, the fourth doped silicon layer 48 may be formed on the front side 14 of the solar cell 10. Depending on the doping, the dopant forms a so-called “front floating emitter” or a “front surface field.” Dopant can likewise diffuse into the surface of the semiconductor substrate 12 on the back side 56 and generate a doping layer 49 (FIG. 6). The doping layer 49 may be undesired.

The full-area diffusion, for example, may comprise a furnace diffusion of dopant from a conventional dopant-rich silicate glass, for example, deposited or formed (e.g., by thermal growth in the presence of a dopant) on the front side 54 and the back side 56, or alternatively, the front side 54 only. A borosilicate glass (BSG) or phosphosilicate glass (PSG) may be grown on the surface(s) of a silicon substrate 12 on an increased scale. A silicate glass layer 62 is thus formed on the front side 54 and the back side 56 of the semiconductor substrate 12 in the example shown in FIG. 6. On the back side 56 of the semiconductor substrate 12, the doping layer 49 and the silicate glass layer 62 may be undesirable, and can be either suppressed or later removed, partially or completely. In particular for a solar cell 10 with a p-type semiconductor substrate 12, this diffusion step can also be skipped, so that the doping on the front side 54 of the semiconductor substrate 12 (or on the front side 14 of the solar cell 10) is not higher than the base doping of the semiconductor substrate 12.

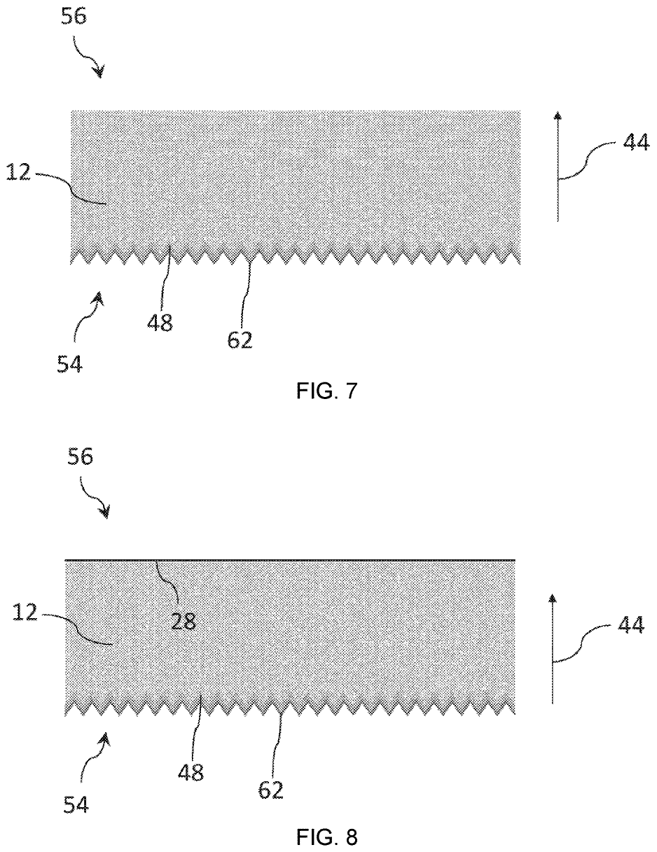

FIG. 7 shows a wet chemical etching back of the back side 56 of the semiconductor substrate 12 (if necessary or desired, in the case in which the silicate glass layer 62 and the doping layer 49 are formed on the back side 56). Thus, the doping layer 49 and the silicate glass layer 62 are removed from the back side 56. For example, the silicate glass layer 62 on the back side 56 can first be etched in an acidic one-sided etching solution. A further alkaline etch etches only the exposed silicon on the back side 56 and removes the doping layer 49. The silicate glass layer 62 on the front side 54 of the semiconductor substrate 12 thereby prevents etching the fourth doped silicon layer 48. An isotropic etch (e.g., for texturing) of the back side 56 of the semiconductor substrate 12 is also conceivable.

Next, the first tunnel layer 28 is formed on the back side 56 of the semiconductor substrate 12 (FIG. 8). The first tunnel layer 28 may be grown or deposited. The thickness of the first tunnel layer 28 may be between 5 and 40 Angstroms. The first tunnel layer 28 may be comprise or consist essentially of a silicon oxide (e.g., SiO₂). Other dielectric materials, or materials that can serve as surface passivation, are also conceivable if they allow passage of charge carriers (e.g., amorphous, intrinsic silicon). The first tunnel layer 28 may optionally also be grown or deposited on the front side 54. However, if formed on the front side 54, the first tunnel layer 28 has little or no influence on the remainder of the method for producing the back-contact solar cell 10, and is therefore not taken into account further.

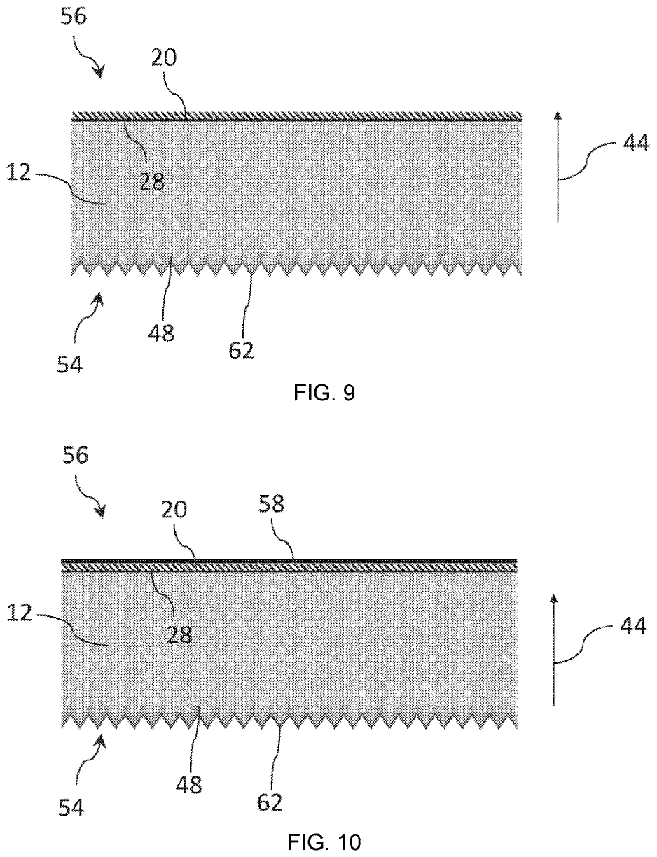

The first doped silicon layer 20 is subsequently formed on the first tunnel layer 28 (FIG. 9) by deposition. The thickness of the first doped silicon layer 20 may be between 20 nm and 400 nm. The first doped silicon layer 20 may have a dopant concentration in a range of from 1×10¹⁹ cm⁻³ to 1×10²¹ cm⁻³. The first doped silicon layer 20 may be deposited, for example, by PVD or chemical vapor deposition (CVD; e.g., low-pressure CVD [LPCVD], plasma-enhanced CVD [PECVD], or atmospheric pressure CVD [APCVD]). In some cases, the first doped silicon layer 20 can also be deposited at least partially on the front side 54 of the semiconductor substrate 12 at the edges thereof. The first doped silicon layer 20 can be deposited in situ doped, or first be deposited intrinsically and subsequently doped ex situ. In ex situ doping, the silicate glass layer 62 on the front side 54 should at least partially serve as a diffusion barrier, in particular if the doping types of the first doped silicon layer 20 and the fourth doped silicon layer 48 are opposite. If the first doped silicon layer 20 is also deposited on the front side 54, it may be removed and/or taken into account in further processing.

Next, an etch-stable barrier layer 58 is formed on the first doped silicon layer 20 (see FIG. 10) by deposition. The barrier layer 58 can comprise or consist essentially of, for example, silicon nitride (SiNx), a silicon oxide (SiOx) and/or a silicon oxynitride (SiON). The barrier layer 58 may also be or comprise a layer stack or a plurality of layers on the back side 56 of the semiconductor substrate 12. The barrier layer 58 serves as an etching barrier against an alkaline etch in further processing. In the case of ex situ doping of the first doped silicon layer 20, it is also possible, for example, to use the silicate glass from the furnace diffusion which has been grown or otherwise formed on the semiconductor substrate 12 as the barrier layer 58. The barrier layer 58 may also cover the front side 54 completely or only partially, e.g. at the edges. The optional barrier layer 58 on the front side 54 is not shown in FIG. 10, but can be taken into account or removed in further processing if present on the front side 54.

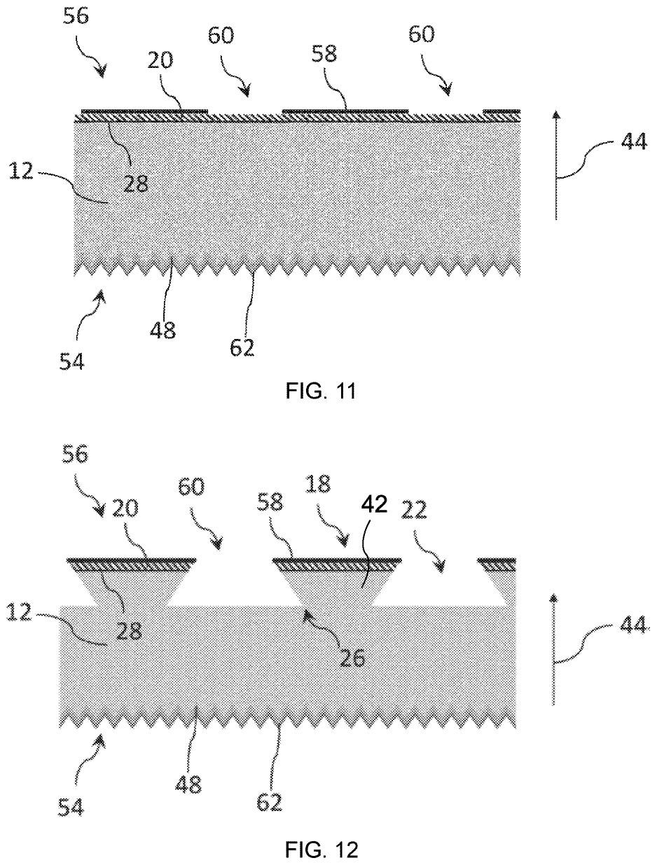

After the barrier layer 58 has been formed, it is removed in a plurality of etching regions 60 (FIG. 11). The barrier layer 58 can be selectively removed from the etching regions 60, for example, by laser ablation. The ablation width may be between 50 μm and 2000 μm. The distance (center-center) between two etching regions 60 may be from 100 μm to 3000 μm, or any value or range of values therein (e.g., between 200 μm and 3000 μm). Ablation can be linear and result in a so-called “interdigitated” pattern. The interdigitated pattern can be interrupted in regions containing the bus bars of the solar cell 10. During the removal of the barrier layer 58 in the etching regions 60, the first doped silicon layer 20 and/or the first tunnel layer 28 can also be partially or completely removed. In addition, the semiconductor structure 12 on its back side 56 can also be partially removed. The etching regions 60 are then etched, wherein the pedestal-like elevations 42 of the semiconductor substrate 12 are produced (FIG. 12). The resulting first regions 18 are on the elevations 42, and the second regions 22 are between the elevations 42. In this case, in particular, the first doped silicon layer 20, the first tunnel layer 28 and portions of the semiconductor substrate 12 on the back side 56 in the etch regions 60 are removed by etching. The first doped silicon layer 20, the first tunnel layer 28 and the portions of the semiconductor substrate 12 can be etched with an acidic or alkaline solution, which is typically aqueous and which may isotropically or anisotropically remove the silicon of the semiconductor substrate 12, and optionally, the silicon of the first doped silicon layer 20 and the material of the first tunnel layer 28. In this case, the barrier layer 58 (outside the etching regions 60) is not etched or is etched only very slowly, so that no etching, or only slight etching, of the first doped silicon layer 20 occurs outside the etching regions 60 (e.g., in areas under the barrier layer 58 and in a direction parallel to the first direction 44). However, the semiconductor substrate 12 is etched in directions both parallel and perpendicular to the first direction 44 (i.e., under the barrier layer 58). The barrier layer 58, the first doped silicon layer 20 and the first tunnel layer 28 (or parts thereof) are undercut or partially undercut by this perpendicular or non-directional etching of the semiconductor substrate 12, resulting in formation of the third regions 26, which may have a non-zero dimension (e.g., depth) along the first direction 44 (vertical). The depth of the etching regions 60 is determined by the etching depth, and may be between 0.5 μm and 20 μm.

The etching can be on one side only (i.e., the back side 56). When using a batch method, in which both the front side 54 and the back side 56 of the semiconductor substrate (or silicon wafer) 12 is completely immersed in the etching medium or solution, the silicate glass layer 62 can serve as an etch barrier and prevent the front side 54 of the semiconductor substrate 12 from being etched. If, in a previous step, the first doped silicon layer 20 has also been deposited on the front side 54, this front-side silicon layer can be etched until the underlying etching barrier (i.e., the silicate glass layer 62) is exposed. If the barrier layer 58 was also deposited on the front side 54 in a previous step, this can be selectively removed by an (acidic) etch on the front side 54, for example in a one-sided etch. This also applies if an etch-stable silicate glass is grown on the first doped silicon layer 20 during an ex-situ doping. The etch-stable silicate glass can be used as the etch barrier 58 on the back side 56, but should be removed on the front side 54 to etch any doped silicon layer 20 that may be thereon.

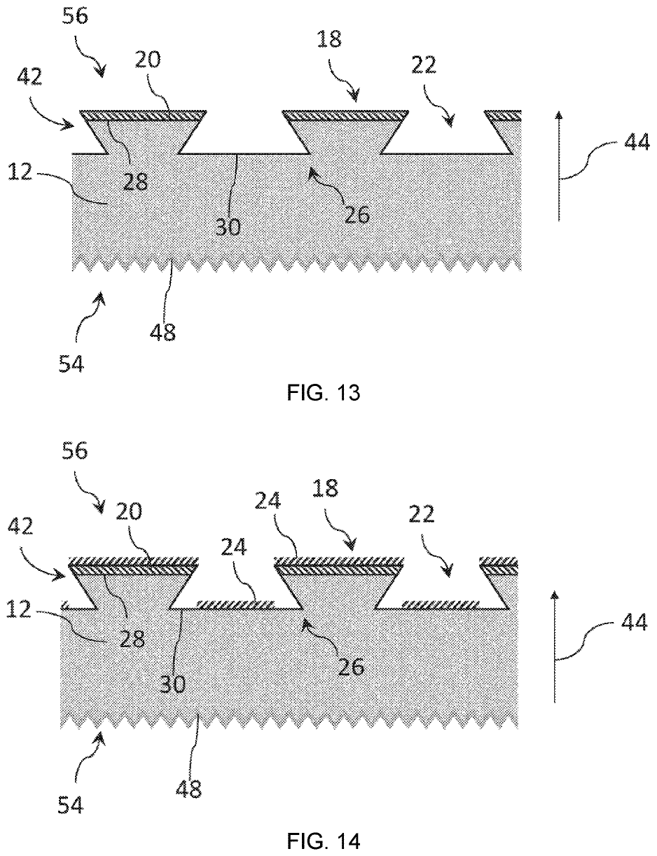

The barrier layer 58 and/or the silicate glass layer 62 can subsequently be completely removed (FIG. 13), for example, by an acidic etching solution. A cleaning step can follow.

In a next step, the second tunnel layer 30 can be formed (FIG. 13). The second tunnel layer 30 may be formed by deposition or growth (e.g., thermal oxidation). The second tunnel layer 30 is formed on the back side 56, where it at least covers areas between the elevations 22 (e.g., the second regions 22), and may additionally cover the third areas 26. However, when formed by deposition, the second tunnel layer 30 may be deposited directionally, so that it covers only the unshaded first and second regions 18 and 22. In addition, the second tunnel layer 30 may also be formed on the front side 54. The second tunnel layer 30 may saturate open bonds at the surface of the semiconductor substrate 12. The second tunnel layer 30 may have a layer thickness of 5 to 40 Angstroms.

Subsequently, the second doped silicon layer 24 is formed (FIG. 14) by deposition. The second doped silicon layer 24 may be deposited by a directional method, for example, PVD (e.g., sputtering, which may optionally pass the sputtered ions through a collimator to enhance its directionality). The second doped silicon layer 24 (e.g., p-type) has, in particular, a doping or polarity opposite to the first doped silicon layer 20 (e.g., n-type). Due to the cross-section of the platform-like elevations 42 widening in the first direction 44, the second doped silicon layer 24 is not formed in the third regions 26. The third regions 26 thus do not contain amorphous, partially crystalline or polycrystalline silicon, or at most contain so little amorphous, partially crystalline or polycrystalline silicon that it can either be removed in a later step, or the resistance of the silicon in the third regions 26 is sufficiently high that it does not or only slightly affects the efficiency of the solar cell. In particular, due to the directed deposition (directed parallel and opposite to the first direction 44), no (or insufficient) material of the second doped silicon layer 24 is deposited in the third regions 26, since the third regions 26 are shaded.

Within the first regions 18, the second doped silicon layer 24 is deposited on the second tunnel layer 30 (if present) and the underlying first doped silicon layer 20. The layer thickness of the second doped silicon layer 24 can be between 20 nm and 400 nm. The second doped silicon layer 24 may have a dopant concentration of from 1×10¹⁹ cm⁻³ to 1×10²¹ cm⁻³, preferably about 5×10¹⁹ cm⁻³ to 2×10²⁰ cm⁻³. In particular, due to the directed deposition, the second doped silicon layer 24 also is not deposited on the front side 54. A high-temperature step for crystallizing the first and second doped silicon layers 20, 24 and for activating the dopants in the first and second doped silicon layers 20, 24 can follow.

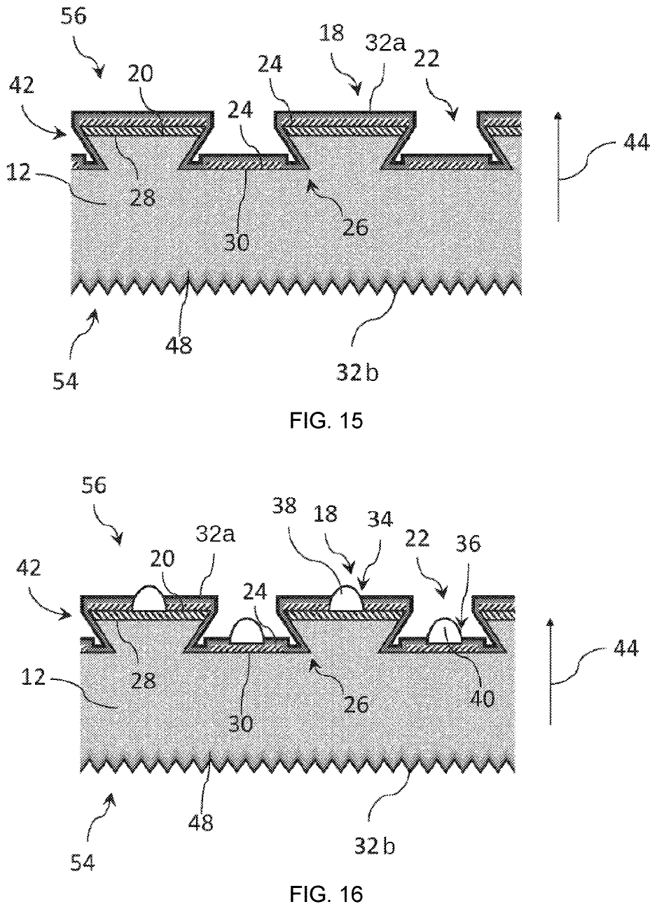

Next, dielectric layer(s) 32a-b for passivating the surfaces of the semiconductor substrate 12 on the front side 54 and the back side 56, respectively, may be deposited (see FIG. 15). The dielectric layer 32 may consist essentially of or comprise one or more layers of dielectric material, for example an aluminum oxide, a silicon oxide (which may be doped or undoped), and/or silicon nitride. One or both of the dielectric layers 32a-b in some embodiments includes two layers. The dielectric layer 32b on the front side 54 and the dielectric layer 32a on the back side 56 can be identical or different, and may in particular have different properties. The deposition process of the dielectric layer(s) 32a-b may be preceded by a wet chemical cleaning step. Hydrogen in the dielectric layer(s) 32a-b (to the extent there is any) can serve to saturate dangling bonds at the surface of the semiconductor substrate 12 in the third regions 26, in the second doped silicon layer 24 in the first and second regions 18 and 22, and optionally in the first doped silicon layer 20 in the first regions 18. The dielectric layer or layer stack 32a-b can also serve as an antireflection coating, in particular on the front side 54, and can increase the light yield or efficiency of the solar cell 10.

The first and the second electrodes 38, 40 can then be formed and/or applied (FIG. 16). The first and/or second electrodes 38, 40 may be arranged such that the first electrodes 38 each contact a first doped silicon layer 20 in the first regions 18, and the second electrodes 40 each contact a second doped silicon layer 24 in the second regions 22. In this case, the first electrodes 38 can respectively penetrate the second doped silicon layer 24 and the second tunnel layer 30 (in the first regions 18). Alternatively, the first electrodes 38 can contact the second doped silicon layer 24 in the first regions 18, without penetrating the second tunnel layer 30 or completely penetrating the second doped silicon layer 24. In other words, the second doped silicon layer 24 may have a non-zero thickness between the first electrodes 38 and the second tunnel layer 30 in the first regions 18.

To contact the electrodes 38, 40, the dielectric layer or layer stack 32a may include the first and second interruptions 34, 36 at locations corresponding to the electrodes 38, 40. The interruptions or openings 34, 36 may be formed, for example, by local ablation (e.g., laser irradiation). Pastes can also be used in the formation of the electrodes 38, 40. The first and/or second interruptions 34, 36 may also be generated during firing of the pastes (e.g., heating and/or irradiating the pastes, optionally while applying a voltage to metallization formed by the pastes) as a result of the pastes (or the resulting metallization) locally dissolving, melting or breaking through the dielectric layer or layer stack 32a. The firing step may also have a positive effect on passivation of the non-metallized surfaces, since hydrogen in the dielectric layer or layer stack 32a may be mobilized at the temperature of the firing step, diffuse to the surfaces of the semiconductor substrate 12 (and the first and second doped silicon layers 20 and 24) and saturate dangling bonds at these surfaces.

The first and/or second interruptions 34, 36 can be continuous (e.g., in the form of lines) or interrupted (e.g., in the form of round circles or points, ovals, squares or segmented lines). The pastes can comprise, for example, a conductive metal, a binder, and optionally, a viscosity-adjusting agent. The conductive metal may include silver, copper, or aluminum. After firing, the particles in the pastes sinter together and form the first and second electrodes 38, 40. The first electrodes 38 and/or the second electrodes 40 can also comprise a layer stack (paste stack), for example, of silver and copper. When using aluminum, the composition of the pastes can be selected such that the aluminum does not alloy with silicon, or alloys only minimally with silicon. Such a composition is suitable for electrodes of both polarities or dopant types.

The composition of the paste(s) can also be selected such that, during firing, any aluminum in the paste(s) alloys with the underlying silicon, and the resulting aluminum-silicon eutectic 50 (e.g., FIG. 3) penetrates through the second doped silicon layer 24 and, when present, the first doped silicon layer 20. In this case, the aluminum can further dope the silicon in the substrate 12 and surrounds the eutectic 50, so that, depending on the polarity of the base, an Al-doped emitter or an Al-doped back-side field can result. Such an alloying paste is suitable in particular for positive electrodes. For negative electrodes, an n-type dopant may be added to the paste such that, after forming the eutectic, an n-type doped silicon layer (e.g., layer 52 in FIG. 3) surrounds the eutectic (e.g., structure 50 in FIG. 3), and the paste is suitable for forming negative electrodes.

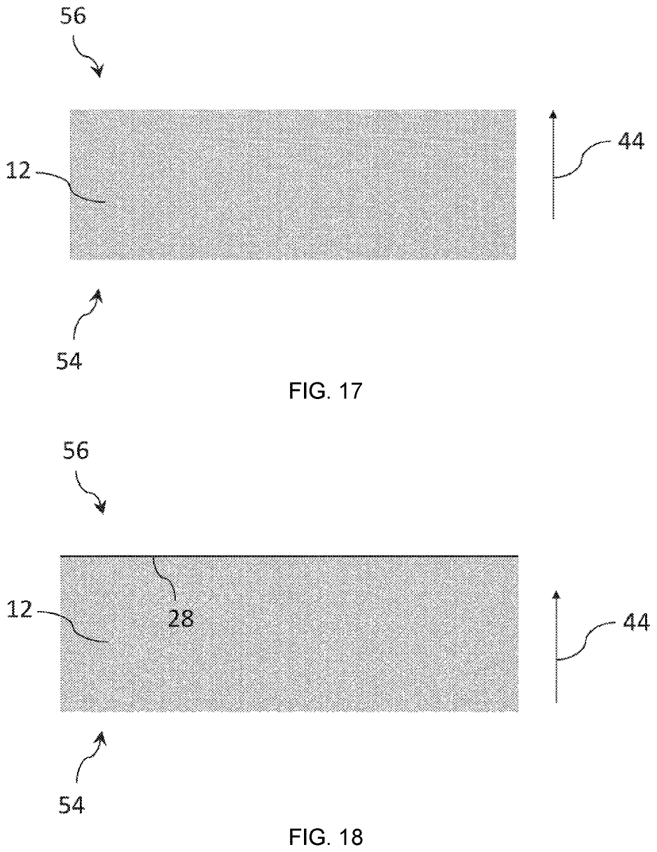

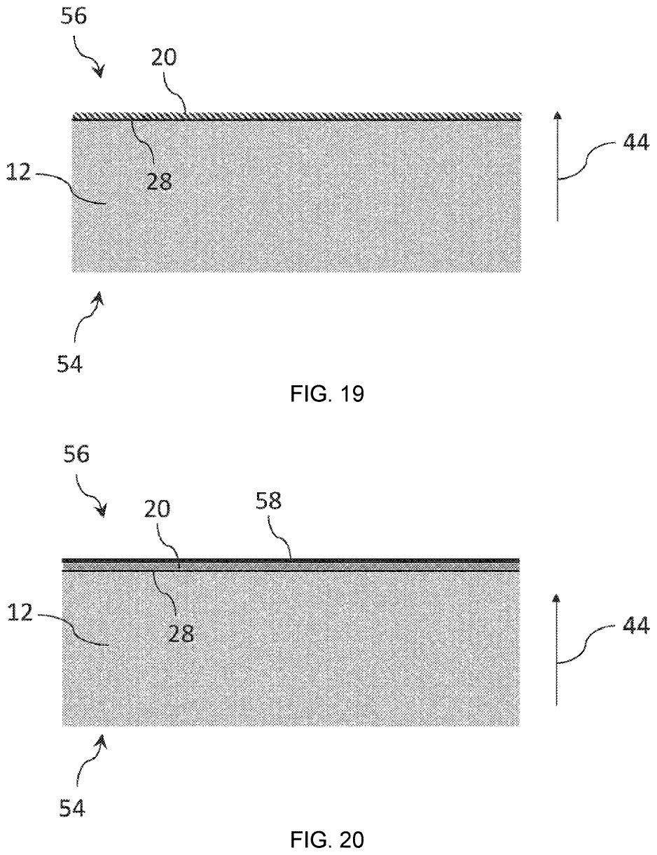

FIGS. 17 to 28 show a method for producing a solar cell 10′ or 10″ with back side contacts according to a second exemplary embodiment. With the method shown, the solar cell 10′ or 10″ can be produced according to the above embodiments, in particular according to the first embodiment shown in FIG. 2.

In a first step, the semiconductor substrate 12 is etched with an anisotropic etch to remove any saw damage and to produce a semiconductor substrate 12 with a planar front side 54 and a planar back side 56 (FIG. 17).

Next (analogously to the first exemplary embodiment of the method), the first tunnel layer 28, then the first doped silicon layer 20 and then the barrier layer 58 are formed on the back side 56 of the semiconductor substrate 12 (FIGS. 18, 19 and 20). In this case, the first tunnel layer 28 can have a layer thickness of 5 to 40 angstroms, the first doped silicon layer 20 can have a layer thickness of 20 nm to 400 nm, and the barrier layer 58 can be formed analogously to the first exemplary embodiment of the method. The first tunnel layer 28 may also be thermally grown. The first tunnel layer 28, the first doped silicon layer 20, and/or the barrier layer 58 may completely cover the back side 56 of the semiconductor substrate 12. The first tunnel layer 28, the first doped silicon layer 20 and/or the barrier layer 58 may also partly (in particular, only at the edges) or completely cover the front side 54 of the semiconductor substrate 12.

The first doped silicon layer 20 may be deposited with a dopant in situ (e.g., with a dopant concentration of from 1×10¹⁹ cm⁻³ to 2×10²¹ cm⁻³), or first deposited intrinsically and subsequently doped ex situ, e.g. by oven diffusion with a doped silicate glass thereon. If a silicate glass is formed or grown on the surface of the first doped silicon layer 20 prior to or during the oven or furnace diffusion, this can optionally be used as a barrier layer 58. The dopant diffused into the first doped silicon layer 20 can be either an n-type dopant or a p-type dopant (see, e.g., Table 1). The barrier layer 58 can comprise a dielectric layer, for example SiOx, SiON or SiNx, or a layer stack or a plurality of (such) dielectric layers.

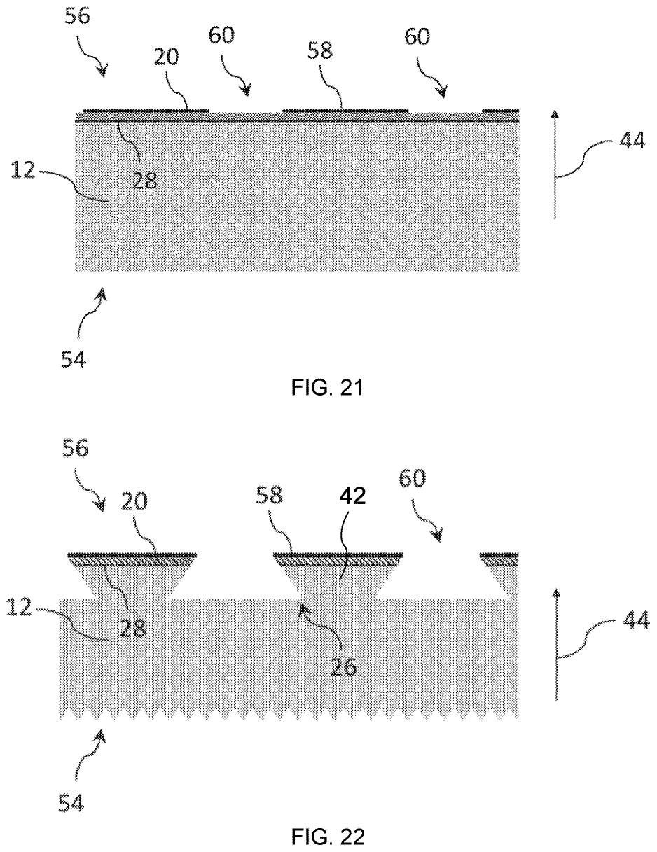

Subsequently (analogously to the first exemplary embodiment of the method), the barrier layer 58 is locally and/or selectively removed, to form etching regions 60 (FIG. 21), for example, by laser ablation. In this case, the first doped silicon layer 20 and/or the first tunnel layer 28 can also be removed at least partially or completely in the etching regions 60. In addition, the semiconductor substrate 12 (on its back side 56) can be removed at least partially in the etching regions 60 by the laser ablation.

A wet chemical etching step is then carried out for removing (if still present) the first doped silicon layer 20, the first tunnel layer 28 and part of the semiconductor substrate 12 from the etching regions 60 (FIG. 22). In this case, approximately 0.5 μm to 20 μm of the semiconductor substrate 12 can be removed in the etching regions 60. Etching with an aqueous alkaline silicon etch solution can be carried out on one side only (on the back side 56) or can also be carried out on both sides (e.g., also on the front side 54). In this case, the layers which may have been deposited or formed on the front side 54 in the preceding steps should likewise be etched, if appropriate and/or required, with an additional one-sided etch.

It is likewise conceivable to clean and/or etch the front side 54 in an earlier or later method step. By etching the front side 54, a textured surface of the front side 54 can be created. It is important that etching the back side 56 leads to undercutting of the barrier layer 58 and, if appropriate, of the first doped silicon layer 20, so that undercut regions and elevated regions are formed (i.e., the third regions 26 and the elevations 42). The third (undercut) regions 26 are provided along the first direction 44 (perpendicular) by the barrier layer 58 and, in most cases, the first doped silicon layer 20. The third (underetch) regions 26 may be formed regardless of whether etching is isotropic or anisotropic. In particular, in the case of an isotropic etch, the surface(s) of the third regions 26 can be textured and provided with an inclination (e.g., a non-zero and non-perpendicular angle), as illustrated in FIG. 4.

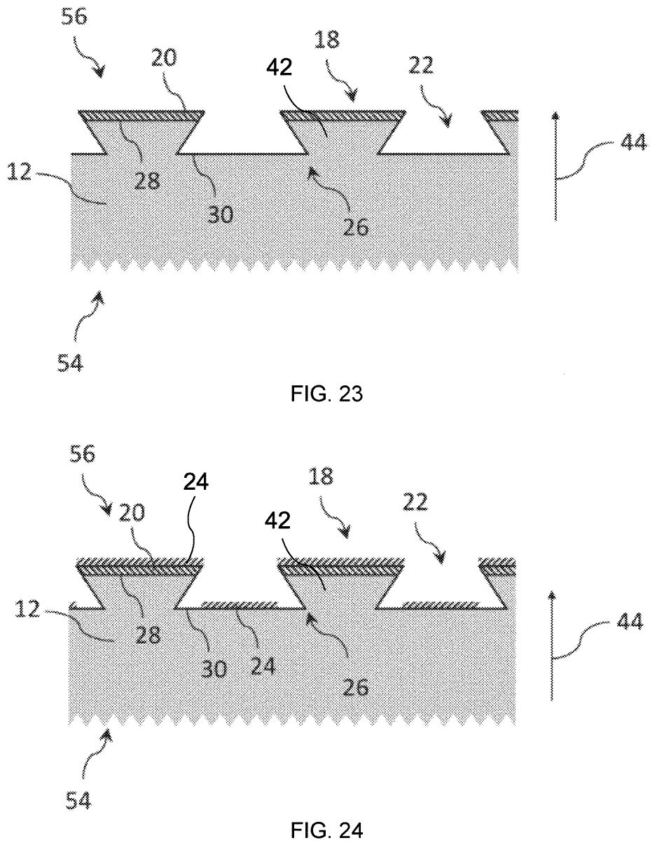

After the etching, the second tunnel layer 30 is formed by growing (e.g., thermal oxidation) or deposition (see FIG. 23). The second tunnel layer 30 may have a thickness of 5 to 40 Angstroms. The second tunnel layer 30 may be grown or deposited non-directionally, such that it is formed in the first, second and third regions 18, 22, 26. Alternatively, the second tunnel layer 30 may be deposited directionally, so that it covers only the unshaded first and second regions 18 and 22 on the back side 56. The second tunnel layer 30 may also be formed on the front side 54.

Thereafter, the second doped silicon layer 24 is formed (see FIG. 24) by directed deposition, for example by physical vapor deposition (PVD; e.g., sputtering, as described herein). In this case, the second doped silicon layer 24 is deposited on the entire unshaded surface on the back side 56 of the semiconductor substrate 12. In the undercut or shaded third regions 26, the second doped silicon layer 24 is not deposited. The second doped silicon layer 24 is thus interrupted by the third regions 26. Within the second regions 22, the second doped silicon layer 24 is also not in contact with the first doped silicon layer 20 (e.g., in the first regions 18).

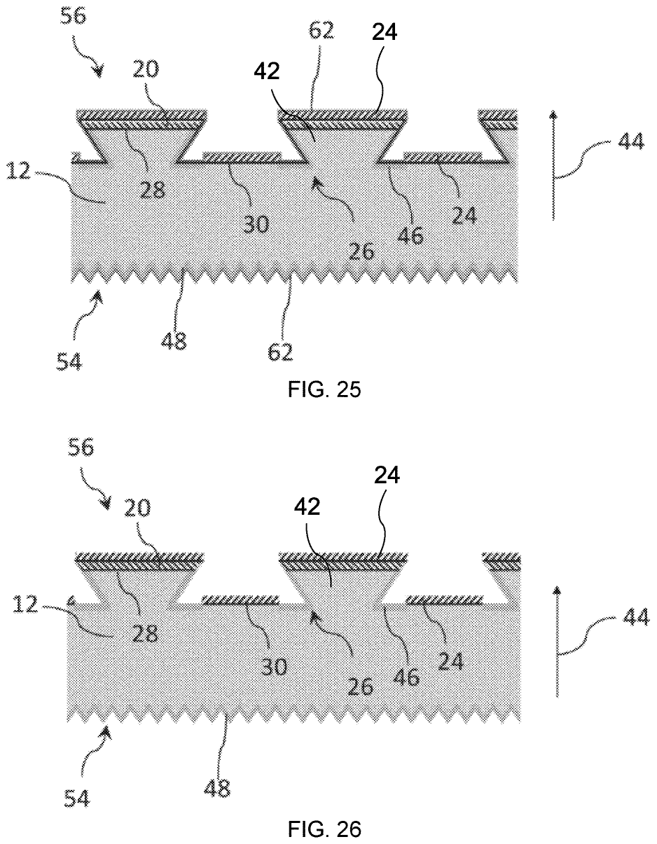

The second doped silicon layer 24 can either be deposited and doped in situ or be deposited intrinsically and subsequently doped, for example in a furnace diffusion process as described herein (FIG. 25). A further layer can be deposited on the second doped silicon layer 24 by PVD, which further layer can function as a diffusion barrier in the following process.

The further layer (not shown) on the second doped silicon layer 24 can prevent further doping of the second doped silicon layer 24 during the furnace diffusion process. Thus, for example, in the third (underetched) regions 26, a dopant having a type or polarity opposite to the second doped silicon layer 24 can be diffused into the semiconductor substrate 12 in the third regions 26 to form a third doped silicon layer 46. The second doped silicon layer 24 and the first doped silicon layer 20 should have dopant types according to Table 1. A high-temperature step may be required for forming a charge carrier-selective contact, which (re)crystallizes the amorphous, partially crystalline or polycrystalline silicon of the first doped silicon layer 20 and the second doped silicon layer 24 and activates the dopants.

FIG. 25 shows such a furnace diffusion process of a dopant, for example. Boron or phosphorus may be diffused to form the fourth doped silicon layer 48 on the front side 54. It can prove to be advantageous if the back side 56 is also completely or at least partially doped in the same process. In this case, the doping in the third regions 26 is the same or similar (e.g., in type and concentration) as on the front side 54. In other words, the third doped silicon layer 46 is formed. The second doped silicon layer 24 can either (i) also be doped during this diffusion process if the second doped silicon layer 24 has been intrinsically deposited or (ii) at least be further doped if the second doped silicon layer 24 is not covered by a diffusion barrier.

The dopant concentration in the second doped silicon layer 24 may be different from the dopant concentration in the third regions 26 and the dopant concentration of the fourth doped silicon layer 48 because the diffusion rate in amorphous, partially crystalline or polycrystalline silicon is higher than in the monocrystalline semiconductor substrate 12.

During the diffusion step, in particular in the case of furnace diffusion, a silicate glass layer 62, for example a borosilicate glass (BSG) or a phosphosilicate glass (PSG), can grow or be deposited on the front side 54 and the back side 56 (FIG. 25). The method step illustrated in FIG. 25 can be omitted, in particular in the case of a p-type semiconductor substrate 12, so that no increase in doping occurs on the front side 54 (and thus in the fourth doped silicon layer 48) or in the third regions 26 (and thus in the third doped silicon layer 46). In this case, the second doped silicon layer 24 may be deposited and doped in situ.

In a further step, the silicate glass layer 62 on the front side 54 and the back side 56 can be removed by wet cleaning (e.g., with a liquid-phase chemical or solution; FIG. 26). In a separate or simultaneous etching step, the second tunnel layer 30 in the third regions 26 (if present) can also be removed. The second tunnel layer 30 may be removed in the same etching step as the silicate-glass layer 62. In other words, the second tunnel layer 30 and the silicate glass layer 62 (if present) can be removed together (or by the same etch).

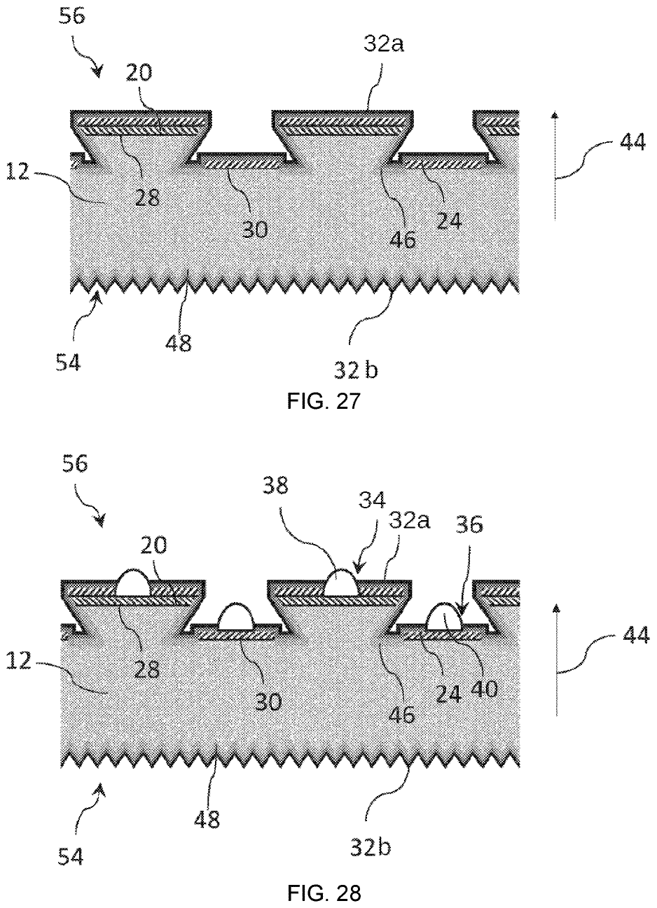

FIGS. 27 and 28 illustrate the formation of the dielectric layer or dielectric layer stack 32b on the front side 54 and the dielectric layer or dielectric layer stack 32a on the back side 56, and the formation of the first and second electrodes 38, 40. In various embodiments, one or both of the dielectric layers or dielectric layer stacks 32a-b comprise of consist essentially of two layers.

The individual steps of the methods described above, as well as the features of the exemplary embodiments of the method and/or the solar cell, can be freely combined and/or supplemented with one another.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A back-contact solar cell comprising a semiconductor substrate, a front side and a back side, wherein:
the back side of the solar cell comprises a plurality of first regions, a plurality of second regions, and a plurality of third regions,
each of the first regions includes a first tunnel layer on the semiconductor substrate and a first doped silicon layer on the first tunnel layer,
each of the second regions includes a second tunnel layer on the semiconductor substrate and a second doped silicon layer on the second tunnel layer,
each of the first doped silicon layers and the second doped silicon layers is amorphous, partially crystalline or polycrystalline,
each of the third regions does not contain amorphous, partially crystalline or polycrystalline silicon,
the back side of the solar cell is at least partially covered in the first and second regions with a first dielectric layer or a first dielectric layer stack,
the first dielectric layer or the first dielectric layer stack in each of the first regions includes a first interruption and in each of the second regions includes a second interruption,
the solar cell comprises a plurality of first electrodes and a plurality of second electrodes, wherein the first electrodes contact the first doped silicon layer through the first interruptions, and the second electrodes contact the second doped silicon layer through the second interruptions, and
the first regions are on elevations of the semiconductor substrate, wherein each of the elevations has a cross-section widening in a first direction, the first direction being perpendicular to the back side of the solar cell.

2. The back-contact solar cell according to claim 1, wherein the third regions are undercut regions.

3. The back-contact solar cell according to claim 1, wherein the third regions are undoped.

4. The back-contact solar cell according to claim 1, wherein each of the third regions includes a third doped silicon layer.

5. The back-contact solar cell according to claim 1, further comprising a fourth doped silicon layer on the front side of the solar cell.

6. The back-contact solar cell according to claim 1, wherein the first doped silicon layers, the second doped silicon layers, the first tunnel layers and/or the second tunnel layers are free of openings.

7. The back-contact solar cell according to claim 1, further comprising an aluminum-silicon eutectic passing through (i) the first doped silicon layers and the first tunnel layers and/or (ii) the second doped silicon layers and the second tunnel layers.

8. The back-contact solar cell according to claim 1, wherein each of the first regions and the second regions are passivating contacts.

9. The back-contact solar cell according to claim 1, wherein the front side is at least partially covered with a second dielectric layer or a second dielectric layer stack.

10. The back-contact solar cell according to claim 1, wherein the elevations are platform-like elevations.

11. The back-contact solar cell according to claim 1, wherein the third regions have a width in a range from 0.5 μm to 20 μm.

12. The back-contact solar cell according to claim 1, wherein the semiconductor substrate comprises monocrystalline silicon.

13. The back-contact solar cell according to claim 1, wherein the first dielectric layer or a first dielectric layer stack is also in the third regions.

14. The back-contact solar cell according to claim 1, wherein the second tunnel layer is also in the third regions, between the semiconductor substrate and the first dielectric layer or the first dielectric layer stack.

15. The back-contact solar cell according to claim 1, wherein each of the first regions further includes the second tunnel layer on the first doped silicon layer, and the second doped silicon layer on the second tunnel layer.

16. A method for producing a back-contact solar cell, comprising:
forming a first tunnel layer on a back side of a semiconductor substrate;
forming a first doped silicon layer having a first polarity on the first tunnel layer;
forming an etch-stable barrier layer on the first doped silicon layer;
removing the etch-stable barrier layer in a plurality of etch regions;
etching the etching regions to form elevations of the semiconductor substrate having a cross-section widening in a first direction, the first direction being perpendicular to the back side of the solar cell;
removing the etch-stable barrier layer;
forming a second tunnel layer in regions between the elevations of the semiconductor substrate; and
forming a second doped silicon layer with a second polarity opposite to the first polarity in regions between the elevations exposed in the first direction, wherein the second doped silicon layer is not formed in third regions between the elevations of the semiconductor substrate and the regions between the elevations exposed in the first direction.

17. The method according to claim 16, further comprising:
forming third doped silicon layers in the third regions and/or fourth doped silicon layer on a front side of the semiconductor substrate by furnace diffusion.

18. The method according to claim 17, further comprising:
removing a silicate glass layer formed during the furnace diffusion by etching.

19. The method according to claim 16, further comprising:
forming first and second electrodes using one or more pastes or paste stacks.

20. The method according to claim 19, wherein the one or more pastes or paste stacks contain a p-type dopant or an n-type dopant.
